(19) United States
(12) Patent Application Publication
(10) Pub. No.: US 2023/0421055 A1
(43) Pub. Date: Dec. 28, 2023

(54) ELECTRONIC APPARATUS AND CONTROL METHOD THEREOF

(71) Applicant: SAMSUNG ELECTRONICS CO., LTD., Suwon-si (KR)

(72) Inventor: Shinho KANG, Suwon-si (KR)

(73) Assignee: SAMSUNG ELECTRONICS CO., LTD., Suwon-si (KR)

(21) Appl. No.: 18/244,061

(22) Filed: Sep. 8, 2023

Related U.S. Application Data
(63) Continuation of application No. PCT/KR22/01214, filed on Jan. 24, 2022.

(30) Foreign Application Priority Data
Mar. 8, 2021 (KR) 10-2021-0030429
Jul. 6, 2021 (KR) 10-2021-0088702

(51) Int. Cl. H02M 1/42; H02M 3/335; H05B 47/10

(52) U.S. Cl. CPC H02M 1/4208; H02M 3/335; H05B 47/10; H03K 19/20

(57) ABSTRACT

The present disclosure provides apparatuses including a lighting function and a multimedia function, and control methods thereof. In some embodiments, an electronic apparatus includes a transformation part configured to convert alternating current (AC) power into direct current (DC) power, a power factor correction (PFC) part including a PFC circuit and a PFC control circuit, and a converter part configured to control a voltage output from the PFC part by using a transformer to supply power through an output terminal of the converter part, set a first switch of the converter part to a first state based on the electronic apparatus performing a multimedia function, and set the first switch to a second state based on the electronic apparatus performing a lighting function. The PFC part is configured to control the PFC control circuit, based on a state of the first switch.

### CROSS-REFERENCE TO RELATED APPLICATIONS

This application is a continuation application of International Application No. PCT/KR2022/001214, filed on Jan. 24, 2022, which claims priority to Korean Patent Application No. 10-2021-0030429, filed on Mar. 8, 2021, and Korean Patent Application No. 10-2021-0088702, filed on Jul. 6, 2021, in the Korean Intellectual Property Office, the disclosures of which are incorporated by reference herein in their entireties.

### BACKGROUND

### 1. Field

The disclosure relates to an electronic apparatus and a control method thereof, and more particularly, to an electronic apparatus including a lighting function and a multimedia function, and a control method thereof.

### 2. Description of Related Art

Recently, various types of electronic apparatuses have been developed, such as, but not limited to, multimedia devices, and the demand for compact multimedia devices is increasing. As the demand for compact multimedia devices is increasing, various functions have been added to multimedia devices. For example, a multimedia device may include a multimedia function for outputting a content image and/or a lighting function.

However, functions of a multimedia device and a lighting device are different from each other and thus standard conditions therefor are also different from each other. Consequently, standards for performing the multimedia function by the multimedia device may be different from those for performing the lighting function by the multimedia device. For example, total harmonic distortion (THD) standards for performing a multimedia function may be satisfied when power consumption of a multimedia device may exceed 75 Watts (W). THD standards for performing a lighting function may be satisfied when the power consumption of the multimedia device may exceed 25 W. Furthermore, in some countries, the THD standards for performing the lighting function may be satisfied when the power consumption of the multimedia device may be less than 5 W and/or greater than 25 W.

A power supply of a multimedia device may need a power factor correction (PFC) function in order to potentially meet the THD standard. However, volume (e.g., size) and/or costs of the power supply may be increased in order to satisfy the THD standards needed under various conditions. Therefore, there exists a need for a compact power supply that may satisfy the THD standards under various conditions.

### SUMMARY

Provided are an electronic apparatus including a compact power supply that may satisfy a total harmonic distortion (THD) standard in a multimedia device to which a lighting function is added, and a control method thereof.

According to an aspect of the disclosure, an electronic apparatus is provided. The electronic apparatus includes a transformation part configured to convert alternating current (AC) power into direct current (DC) power, a power factor correction (PFC) part including a PFC circuit and a PFC control circuit, and a converter part configured to control a voltage output from the PFC part by using a transformer to supply power through an output terminal of the converter part, set a first switch of the converter part to a first state based on the electronic apparatus performing a multimedia function, and set the first switch to a second state based on the electronic apparatus performing a lighting function. The PFC part is configured to control the PFC control circuit, based on a state of the first switch.

According to an aspect of the present disclosure, an electronic apparatus is provided. The electronic apparatus includes a transformation part configured to convert AC power into DC power, a PFC part including a PFC circuit, a PFC control circuit, a first comparator, an AND gate, and a second switch, and a converter part including a first switch and an output current monitoring circuit. The second switch is coupled to a power terminal of the PFC control circuit and is configured to be controlled by a signal output from the AND gate. An input terminal of the AND gate is coupled to an output terminal of the first comparator and a first terminal of the first switch. A second terminal of the first switch is coupled to a ground voltage. The converter part is configured to supply power through an output terminal of the converter part by controlling a first voltage output from the PFC part by using a transformer, identify an output current of the power output through the output terminal of the converter part by using the output current monitoring circuit, and control the first switch based on the identified output current. The PFC part is configured to control power to be supplied to the PFC control circuit by controlling the second switch based on a state of the first switch and a signal output from the first comparator.

According to an aspect of the present disclosure, a control method of an electronic apparatus is provided. The control method includes converting AC power into DC power, controlling a PFC part, and supplying power by using a converter part by controlling a voltage output from the PFC part by using a transformer. The controlling of the PFC part includes setting a first switch of the converter part to at least one of a first state and a second state, based on an operating mode of the electronic apparatus, and controlling a PFC control circuit of the PFC part based on a state of the first switch. The operating mode of the electronic apparatus corresponds to at least one of a multimedia function and a lighting function.

Additional aspects may be set forth in part in the description which follows and, in part, may be apparent from the description, and/or may be learned by practice of the presented embodiments.

### BRIEF DESCRIPTION OF THE DRAWINGS

The above and/or other aspects, features, and advantages of certain embodiments of the present of the disclosure may be more apparent from the following description taken in conjunction with the accompanying drawings, in which:

FIG. 1 is a perspective view illustrating an exterior of an electronic apparatus, according to an embodiment of the disclosure;

FIG. 2 is a block diagram illustrating a configuration of an electronic apparatus, according to an embodiment of the disclosure;

FIG. 3 is a perspective view illustrating the exterior of an electronic apparatus, according to an embodiment of the disclosure;

FIG. 4 is a perspective view illustrating the exterior of an electronic apparatus, according to an embodiment of the disclosure;

FIG. 5 is a perspective view illustrating the exterior of an electronic apparatus, according to an embodiment of the disclosure;

FIG. FIGS. 6A and 6B are perspective views illustrating the exterior of an electronic apparatus, according to an embodiment of the disclosure;

FIG. 7A is a diagram illustrating a power supply of an electronic apparatus for control of a power factor correction (PFC) control circuit according to a function performed, according to an embodiment of the disclosure;

FIG. 7B is a diagram depicting operations of an electronic apparatus when a multimedia function is performed, according to an embodiment of the disclosure;

FIG. 7C is a diagram illustrating operations of an electronic apparatus when a lighting function is performed, according to an embodiment of the disclosure;

FIG. 8 is a diagram illustrating an operation waveform of the electronic apparatus of FIG. 7A, according to an embodiment of the disclosure;

FIG. 9 is a diagram illustrating a power supply of an electronic apparatus for control of a PFC control circuit according to a function to be performed and an input voltage, according to an embodiment of the disclosure;

FIG. 10 is a diagram illustrating an operation waveform of the electronic apparatus of FIG. 9, according to an embodiment of the disclosure;

FIG. 11 is a diagram illustrating an electronic apparatus with a power supply embodied as an adapter, according to an embodiment of the disclosure;

FIG. 12 is a diagram illustrating an operation waveform of the electronic apparatus of FIG. 11, according to an embodiment of the disclosure; and

FIG. 13 is a flowchart of a control method of an electronic apparatus, according to an embodiment of the disclosure.

### DETAILED DESCRIPTION

Hereinafter, various embodiments will be described in more detail with reference to the accompanying drawings. Various changes may be made in the embodiments set forth herein. Example embodiments may be illustrated in the drawings and described in detail in the detailed description. However, the embodiments illustrated in the accompanying drawings are merely intended to help the understanding of various embodiments. Therefore, it may be understood that the technical idea of the disclosure is not limited by the embodiments illustrated in the accompanying drawings and the disclosure includes all equivalents or alternatives included in the spirit and technical scope of the disclosure.

Terms, including ordinal numbers such as second and first, may be used to describe various components but these components are not limited by the terms. The above terms are only used to distinguish one component from another.

It may be understood that the terms “comprise” and/or “comprising”, when used herein, specify the presence of stated features, integers, steps, operations, elements, components, or a combination thereof, but do not preclude the presence or addition of one or more features, integers, steps, operations, elements, components, or a combination thereof. When a component is referred to as being “coupled to” or “connected” to another component, it may be understood that the component may be directly coupled to or connected to the other component but another component may be interposed therebetween. In contrast, when a component is referred to as being “directly coupled” or “directly connected” to another component, it may be understood that no component is interposed therebetween.

In the following description of the disclosure, an order of operations may be understood non-restrictively unless a preceding operation is necessarily logically and temporally performed before a following operation. That is, except for such an exceptional case, even when an operation described later is performed before an operation described earlier, the essence of the disclosure is not changed thereby, and the scope of the disclosure may be defined regardless of the order of operations. As used herein, the expression “A or B” may be defined as selectively indicating A or B or as including both A and B. As used herein, the term “comprise” and “include” should be understood to include not only listed elements but also other elements.

In the present disclosure, only essential elements necessary to describe the disclosure are described, and elements that are not related to the essence of the disclosure are not described. In addition, the disclosure should not be interpreted exclusively to include only components described herein but should be interpreted non-exclusively to include other components.

In the following description of the disclosure, related well-known functions or components are briefly described or not described when it is determined that they would obscure the subject matter of the disclosure due to unnecessary detail. Meanwhile, embodiments may be implemented or performed independently but may be implemented or performed in combination.

The embodiments herein may be described and illustrated in terms of blocks, as shown in the drawings, which carry out a described function or functions. These blocks, which may be referred to herein as units or modules or the like, or by names such as device, logic, circuit, counter, comparator, generator, converter, or the like, may be physically implemented by analog and/or digital circuits including one or more of a logic gate, an integrated circuit, a microprocessor, a microcontroller, a memory circuit, a passive electronic component, an active electronic component, an optical component, and the like, and may also be implemented by or driven by software and/or firmware (configured to perform the functions or operations described herein).

Hereinafter, various embodiments of the present disclosure are described with reference to the accompanying drawings.

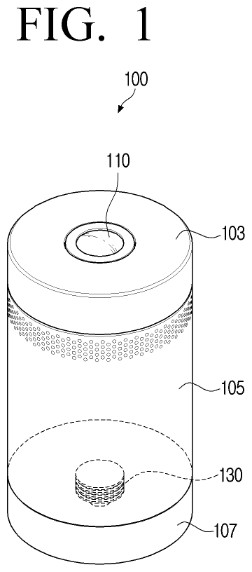

FIG. 1 is a perspective view illustrating an exterior of an electronic apparatus 100 according to an embodiment of the disclosure.

Referring to FIG. 1, the electronic apparatus 100 may include a head 103, a main body 105, a projection lens 110, a connector 130, and/or a cover 107.

The electronic apparatus 100 may be devices in various forms. For example, the electronic apparatus 100 may be and/or may include a projector device that may enlarge and/or project an image to a wall or a screen. For another example, the projector device may be and/or may include a liquid crystal display (LCD) projector and/or a digital light processing (DLP) type projector that uses a digital micromirror device (DMD).

Alternatively or additionally, the electronic apparatus 100 may be a home or industrial display device, an illumination device used in daily life, or an audio device including an audio module. The electronic apparatus 100 may be implemented as a portable communication device (e.g., smartphone), a computer device, a portable multimedia device, a wearable device, a home appliance device, or the like. The electronic apparatus 100, according to an embodiment of the disclosure, is not limited to the above-described device, and may be implemented as an electronic apparatus 100 having two or more functions of the above-described devices. For example, the electronic apparatus 100 may be used as the display device, the illumination device or the audio device while its projector function may be turned off and its illumination function or a speaker function may be turned on based on a manipulation of the processor, and/or may be used as an artificial intelligence (AI) speaker including a microphone and/or a communication device.

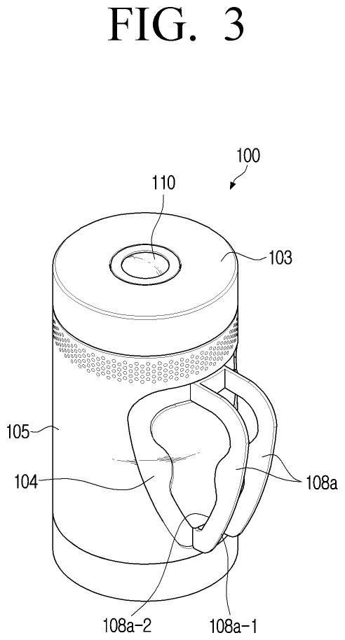

The main body 105 may include a housing constituting the exterior. Alternatively or additionally, the main body 105 may support and/or protect components of the electronic apparatus 100 (e.g., components illustrated in FIG. 3) arranged inside the main body 105. In an embodiment, a shape of the main body 105 may be substantially similar to a cylindrical shape as shown in FIG. 1. However, the shape of the main body 105 is not limited thereto, and according to various embodiments of the disclosure, the main body 105 may be implemented in various geometrical shapes such as, but not limited to, a column having polygonal cross sections, a cone, or a sphere.

The main body 105 may have a size enabling the main body to be gripped and/or moved by a user with his/her hand. Alternatively, the main body 105 may be implemented in a micro size enabling the main body to be easily carried by the user and/or a size enabling the main body to be held on a table and/or coupled to the illumination device.

A material of the main body 105 may be a matte metallic and/or a synthetic resin that may prevent the user's fingerprints and/or dust from smearing the main body 105. Alternatively, the exterior of the main body 105 may be made of a slick glossy material.

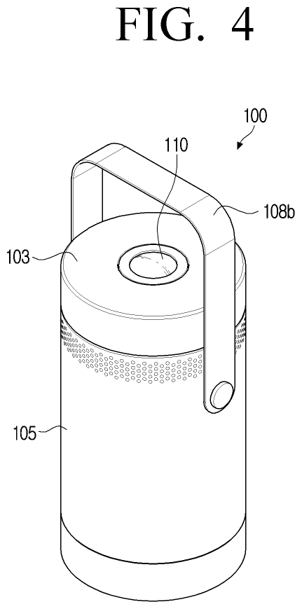

The main body 105 may have a friction area formed in a partial area of the exterior of the main body 105 for the user to grip and move the main body 105. Alternatively, the main body 105 may have a bent gripping part and/or a support (e.g., support 108b of FIG. 4) positioned in at least a partial area for the user to grip the corresponding part.

The projection lens 110 may be formed on one surface of the main body 105. The projection lens 110 may project light passed through a lens array to outside the main body 105. The projection lens 110, according to the various embodiments of the disclosure, may be and/or may include an optical lens that may be low-dispersion coated for reducing chromatic aberration. The projection lens 110 may be a convex lens and/or a condensing lens. The projection lens 110, according to an embodiment of the disclosure, may adjust a focus by adjusting positions of a plurality of sub lenses.

The head 103 may be coupled to one surface of the main body 105, and thus, may support and/or protect the projection lens 110. The head 103 may be coupled to the main body 105 to be swiveled within a predetermined angle range based on one surface of the main body 105.

The head 103 may be automatically and/or manually swiveled by the user and/or the processor in order to adjust a projection angle of the projection lens 110. Alternatively, the head 103 may include a neck that may be coupled to the main body 105 and may extend from the main body 105, and the head 103 may thus adjust the projection angle of the projection lens 110 by being tilted backward and/or forward.

The electronic apparatus 100 may project light and/or the image to a desired position by adjusting a projection angle of the projection lens 110 while adjusting a direction of the head 103 in a state where the position and angle of the main body 105 may be fixed. Alternatively or additionally, the head 103 may include a handle that the user may grip after rotating the head in a desired direction.

A plurality of openings may be formed in an outer circumferential surface of the main body 105. Through the plurality of openings, audio output from an audio outputter may be output to outside the main body 105 of the electronic apparatus 100. The audio outputter may be and/or may include a speaker. The speaker may be used for general uses such as, but not limited to, reproduction of multimedia, reproduction of a recording, and/or output of a voice.

According to an embodiment of the disclosure, the main body 105 may include a radiation fan provided therein. When the radiation fan is operated, air or heat in the main body 105 may be discharged through the plurality of openings. Accordingly, the electronic apparatus 100 may discharge heat occurring due to the driving of the electronic apparatus 100 to the outside, and may prevent overheating of the electronic apparatus 100.

The connector 130 may connect the electronic apparatus 100 with an external device to transmit and/or receive electronic signals. The electronic apparatus 100 may also receive power from the external device. The connector 130, according to an embodiment of the disclosure, may be physically connected with the external device. The connector 130 may include an input/output interface to connect its communication with the external device in a wired and/or wireless manner. Alternatively or additionally, the connector 130 may receive the power from the external device. For example, the connector 130 may include, but not be limited to, a high-definition multimedia interface (HDMI) connection terminal, a universal serial bus (USB) connection terminal, a secure digital (SD) card accommodating groove, an audio connection terminal, a power consent, and the like. Alternatively or additionally, the connector 130 may include a Bluetooth™, wireless-fidelity (Wi-Fi), and/or wireless charge connection module, connected with the external device in the wireless manner.

Alternatively or additionally, the connector 130 may have a socket structure connected to an external illumination device. The connector 130 may be connected to a socket accommodating groove of the external illumination device to receive the power. The size and specification of the connector 130 having the socket structure may be implemented in various ways in consideration of an accommodating structure of the external device that may be coupled thereto. For example, a diameter of a joining portion of the connector 130 may be 26 millimeters (mm) according to an international standard E26. In such an example, the electronic apparatus 100 may be coupled to the external illumination device such as, but not limited to, a stand in place of a light bulb that may be generally used. When being coupled to a conventional socket positioned on a ceiling, the electronic apparatus 100 may vertically perform the projection. Accordingly, the socket-coupled electronic apparatus 100 may not be rotated. Alternatively or additionally, the screen may not be rotated either. Accordingly, the electronic apparatus 100 may project and/or rotate the screen to a desired position while being socket-coupled to a stand on the ceiling by allowing the head 103 to swivel on one surface of the main body 105 to have an adjusted projection angle for the electronic apparatus 100 to be rotated even when being socket-coupled and receiving power.

The connector 130 may include a coupling sensor. The coupling sensor may detect whether the connector 130 is coupled to the external device, the connector 130 is in a coupling state, and/or the connector 130 is a coupling target. The coupling sensor may transmit the same to the processor. The processor may control the driving of the electronic apparatus 100 based on a received detection value.

The cover 107 may be coupled to and/or separated from the main body 105, and protect the connector 130 and/or may prevent the connector 130 from being exposed to the outside. The cover 107 may have a shape continued from the shape of the main body 105, as shown in FIG. 1, and/or a shape corresponding to the shape of the connector 130. The cover 107 may support the electronic apparatus 100, and the electronic apparatus 100 may be used by being coupled to and/or held on an external holder while being coupled to the cover 107.

In the electronic apparatus 100, according to various embodiments of the disclosure, a battery may be positioned inside the cover 107. The battery may include, for example, a primary cell that may not be recharged, a secondary cell that may be recharged, a fuel cell, and the like.

In an embodiment, the electronic apparatus 100 may include a camera module. The camera module may capture a still image and/or a video. According to an embodiment of the disclosure, the camera module may include at least one lens, an image sensor, an image signal processor, and/or a flash.

The electronic apparatus 100 may include a protection case for the electronic apparatus 100 to be carried while being protected. Alternatively, the electronic apparatus 100 may include a stand that may support and/or fix the main body 105, and/or a bracket that may be coupled to a wall surface and/or a partition.

Alternatively or additionally, the electronic apparatus 100 may be connected with the various external devices by using the socket structure, and may provide various functions. For example, the electronic apparatus 100 may be connected to an external camera device by using the socket structure. The electronic apparatus 100 may provide an image stored in the connected camera device and/or an image that may be currently being captured using a projecting part 210. For an example, the electronic apparatus 100 may be connected to a battery module by using the socket structure to receive power. The electronic apparatus 100 may be connected to the external device by using the socket structure, which is merely an example, and may be connected to the external device by using another interface (e.g., USB).

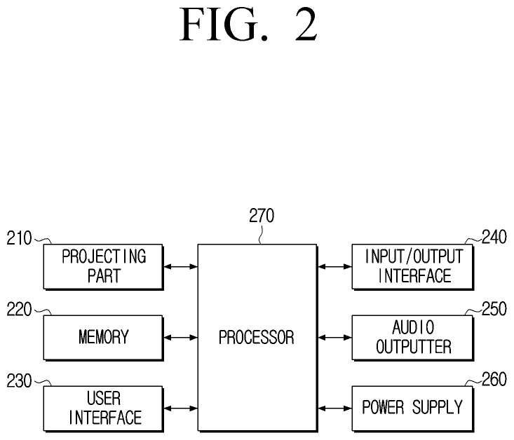

FIG. 2 is a block diagram illustrating a configuration of the electronic apparatus 100, according to an embodiment of the disclosure. Referring to FIG. 2, the electronic apparatus 100 may include the projecting part 210, the memory 220, a user interface 230, an input/output interface 240, an audio outputter 250, a power supply 260, and the processor 270.

The number and arrangement of components of the electronic apparatus 100 shown in FIG. 2 are provided as an example. In practice, there may be additional components, fewer components, different components, or differently arranged components than those shown in FIG. 2. Furthermore, two or more components shown in FIG. 2 may be implemented within a single component, or a single component shown in FIG. 2 may be implemented as multiple, distributed components. Alternatively or additionally, a set of (one or more) components shown in FIG. 2 may be integrated with each other, and/or may be implemented as an integrated circuit, as software, and/or a combination of circuits and software.

The projecting part 210 may be a component that may project the image to the outside. The projecting part 210, according to an embodiment of the disclosure, may be implemented in various projection types (e.g., cathode-ray tube (CRT) type, LCD type, DLP type, laser type, and the like). For example, a principle of operation of the CRT type may be substantially similar and/or may be the as the principle of operation of a CRT monitor. The CRT type may display the image on the screen by enlarging the image by using a lens in front of a CRT. The CRT type may be divided into a one-tube type and a three-tube type based on the number of cathode-ray tubes. For example, in the three-tube type, the cathode-ray tubes of red, green, and blue may be separated from one another.

In an embodiment, the LCD type may display an image by allowing light emitted from a light source to pass through a liquid crystal. The LCD type may be divided into a single-panel type and a three-panel type. For example, in an LCD of a three-plate type, the light emitted from the light source may be separated into red, green and blue in a dichroic mirror (e.g., a mirror that may reflect only light of a specific color and/or may allow the remaining light to pass therethrough). The three-plate type LCD may pass the separated light through the liquid crystal, and/or may collect the separated light into one place again. That is, the separated light may be recombined.

In an embodiment, the DLP type may display an image by using a digital micromirror device (DMD) chip. The DLP type projecting part may include a light source, a color wheel, the DMD chip, a projection lens, and the like. Light emitted from the light source may be colored by passing through a rotating color wheel. Light passed through the color wheel may be input into the DMD chip. The DMD chip may include numerous micromirrors and/or may reflect light input to the DMD chip. The projection lens may expand light reflected from the DMD chip to the image size.

In another embodiment, the laser type may include a diode pumped solid state (DPSS) laser and a galvanometer. The laser type may output various colors by using a laser in which three DPSS lasers may be respectively installed for red, green, and blue (RGB) colors, and the optical axes of the DPSS lasers may overlap with each other by using a special mirror. The galvanometer may include a mirror and a high-power motor, and may move the mirror at a high speed. For example, the galvanometer may rotate the mirror at up to 40 KHz/sec. The galvanometer may be mounted in a scanning direction. In general, a projector may perform planar scanning, and the galvanometer may also be disposed by being divided into x and y axes.

The projecting part 210 may include light sources of various types. For example, the projecting part 210 may include at least one light source of a lamp, a light emitting diode (LED), and a laser.

The projecting part 210 may output the image in a screen ratio of 4:3, a screen ratio of 5:4, and a wide screen ratio of 16:9, based on a purpose of the electronic apparatus 100, the user's setting or the like, and may output the image having various resolutions such as, but not limited to, wide video graphics array (WVGA, having a resolution of 854×480 pixels), super video graphics array (SVGA, having a resolution of 800×600 pixels), extended graphics array (XGA, having a resolution of 1024×768 pixels), wide extended graphics array (WXGA, having a resolution of 1280×720 pixels and/or 1280×800 pixels), super extended graphics array (SXGA, having a resolution of 1280×1024 pixels), ultra extended graphics array (UXGA, having a resolution of 1600×1200 pixels) and full high-definition (HD, having a resolution of 1920×1080 pixels), based on the screen ratio.

The projecting part 210 may perform various functions for adjusting the output image under the control of the processor 270. For example, the projecting part 210 may perform a zoom function, the keystone function, a quick corner (or four corner) keystone function and a lens shift function, and/or the like.

The projecting part 210 may enlarge and/or reduce the image based its distance (e.g., projection distance) to the screen. That is, the projecting part 210 may perform the zoom function based on a distance of the projecting part 210 to the screen. The zoom function may include a hardware method of adjusting a screen size by moving a lens, and/or a software method of adjusting the screen size by cropping the image, and the like. In a case in which the zoom function is performed, it may be necessary to adjust a focus of the image. For example, a method of adjusting the focus may include a manual focusing method, an electric focusing method, and the like. The manual focusing method may refer to a method of manually adjusting the focus, and the electric focusing method may refer to a method in which the projector automatically adjusts the focus by using a motor built therein when performing the zoom function. When performing the zoom function, the projecting part 210 may provide a digital zoom function through software, and/or may provide an optical zoom function in which the zoom function may be performed by moving the lens by using a driving part.

In addition, the projecting part 210 may perform the keystone function. For example, when a height does not match a front projection, the screen may be distorted up or down. The keystone function may be a function of correcting a distorted screen. For example, in a case in which the distortion occurs on the screen in a horizontal direction, the distortion may be corrected using a horizontal keystone, and in a case in which the distortion occurs on the screen in a vertical direction, the distortion may be corrected using a vertical keystone. The quick corner (and/or four corner) keystone function may be a function of correcting the screen in a case in which a balance between corner areas of the screen may not be appropriate while a central area of the screen may be normal. The lens shift function may be a function of moving the screen as it is in a case in which the screen is outside a screen area.

The projecting part 210 may provide the zoom/keystone/focusing functions by automatically analyzing a surrounding environment and a projection environment without the user input. The projecting part 210 may automatically provide the zoom/keystone/focusing functions, based on the distance between an electronic apparatus 100 and the screen, information about a space where the electronic apparatus 100 is currently positioned, information about an amount of ambient light, or the like, detected by the sensor (e.g., depth camera, distance sensor, infrared sensor, or illumination sensor).

In addition, the projecting part 210 may provide an illumination function by using the light source. That is, the projecting part 210 may provide the illumination function by outputting the light source by using the LED. For example, the projecting part 210 may include one LED, and in an example, the electronic apparatus 100 may include a plurality of LEDs. The projecting part 210 may output the light source by using a surface-emitting LED in an implementation example. The surface-emitting LED may be and/or may include an LED in which an optical sheet is disposed on an upper side of the LED for the light source to be evenly dispersed and output. When being output through the LED, the light source may be evenly dispersed through the optical sheet, and the light source dispersed through the optical sheet may be introduced into a display panel.

The projecting part 210 may provide the user with a dimming function for adjusting intensity of the light source. The projecting part 210 may control the LED to output the intensity of the light source that corresponds to a received user input when receiving the user input for adjusting the intensity of the light source from the user through the user interface 230 (e.g., a touch display button and/or a dial).

In addition, the projecting part 210 may provide the dimming function, based on the content analyzed by the processor 270 without the user input. The projecting part 210 may control the LED to output the intensity of the light source, based on information (e.g., content type or content brightness) on the currently-provided content.

The projecting part 210 may control a color temperature by the control of the processor 270. That is, the processor 270 may control a color temperature based on the content. In a case that it is identified that the content is to be output, the processor 270 may obtain color information for each frame of the content whose output is determined. The processor 270 may then control the color temperature based on the obtained color information for each frame. The processor 270 may obtain at least one main color of the frame based on the color information for each frame. The processor 270 may then adjust the color temperature based on the obtained at least one main color. For example, the color temperature may be divided into a warm type or a cold type. The frame to be output (hereinafter, an output frame) may include a fire scene. The processor 270 may identify (and/or obtain) that the main color is red based on the color information included in the current output frame. The processor 270 may then identify the color temperature corresponding to the identified main color (e.g., red). The color temperature corresponding to the red color may be the warm type. The processor 270 may use an artificial intelligence model to obtain the color information and/or main color of the frame. For example, the artificial intelligence model may be stored in the electronic apparatus 100 (e.g., memory 220). For another example, the artificial intelligence model may be stored in an external server which may communicate with the electronic apparatus 100.

The electronic apparatus 100 may be interlocked with the external device to control the illumination function. The electronic apparatus 100 may receive illumination information from the external device. The illumination information may include at least one of brightness information or color temperature information, which may be set by the external device. The external device may be a device connected to the same network as the electronic apparatus 100 (e.g., Internet of Things (IoT) device included in a same home/work network) or a device not connected to the same network as the electronic apparatus 100 but capable of communicating with the electronic apparatus 100 (e.g., remote control server). For example, an external illumination device (e.g., IoT device) included in the same network as the electronic apparatus 100 may output red light having brightness of 50 lumens (lm). The external lighting device (e.g., IoT device) may directly and/or indirectly transmit the illumination information (e.g., information indicating that the red light is being output with the brightness of 50 lm) to the electronic apparatus 100. The electronic apparatus 100 may control the output of the light source based on the illumination information received from the external illumination device. For example, in a case in which the illumination information received from the external illumination device includes the information indicating that the red light is output with the brightness of 50 lm, the electronic apparatus 100 may output the red light having the brightness of 50 lm.

The electronic apparatus 100 may control the illumination function based on biometric information. The processor 270 may obtain the user's biometric information. The biometric information may include at least one of the body temperature, heart rate, blood pressure, breath or electrocardiogram of the user. The biometric information may include various information other than the aforementioned information. For example, the electronic apparatus 100 may include a sensor for measuring the biometric information. The processor 270 may obtain the biometric information of the user through the sensor, and control the output of the light source based on the obtained biometric information. For an example, the processor 270 may receive the biometric information from the external device through the input/output interface 240. The external device may be the portable communication device (e.g., smart phone or wearable device) of the user. The processor 270 may obtain the biometric information of the user from the external device, and control the output of the light source based on the obtained biometric information. For example, the electronic apparatus 100 may identify whether the user is sleeping and the processor 270 may control the output of the light source based on the user's biometric information in a case that it is identified that the user is sleeping (and/or preparing to sleep).

The memory 220 may store at least one instruction on the electronic apparatus 100. Alternatively or additionally, the memory 220 may store an operating system (O/S) for driving the electronic apparatus 100. The memory 220 may also store various software programs and/or applications for operating the electronic apparatus 100 in various examples of the disclosure. In an embodiment, the memory 220 may include a semiconductor memory such as, but not limited to, a flash memory, and/or a magnetic storing medium such as a hard disk.

The memory 220 may store various software modules for operating the electronic apparatus 100 in various examples of the disclosure. The processor 270 may control the operation of the electronic apparatus 100 by executing the various software modules stored in the memory 220. That is, the memory 220 may be accessed by the processor 270, and the processor 270 may perform readout, recording, correction, deletion, update and the like of data in the memory 220.

As used herein, the term “memory” may include the memory 220, a read only memory (ROM), a random access memory (RAM) in the processor 270, a memory card (e.g., a micro secure digital (SD) card, a memory stick) mounted in the electronic apparatus 100.

The sensor 113 may include at least one sensor. The sensor 113 may include at least one of an inclination sensor for detecting the inclination of the electronic apparatus 100 and an image sensor for capturing the image. The inclination sensor may be and/or may include an acceleration sensor and/or a gyro sensor. The image sensor may be and/or may include the camera module and/or the depth camera. The inclination sensor may be referred to as a motion sensor. In addition, the sensor 113 may include various sensors other than the inclination sensor and/or the image sensor. For example, the sensor 113 may include the illumination sensor and/or the distance sensor. In an embodiment, the sensor 113 may include a light detection and ranging (LIDAR) sensor.

The user interface 230 may include various types of input devices. For example, the user interface 230 may include a physical button. The physical button may include a function key, a direction key (e.g., a four-direction key), or a dial button. For example, the physical button may be implemented as a plurality of keys. For another example, the physical button may be implemented as one key. In a case in which the physical button is implemented as one key, the electronic apparatus 100 may receive the user input in which the one key is pressed for a critical time and/or longer. When receiving the user input in which one key is pressed for the critical time or longer, the processor 270 may perform a function corresponding to the user input. For example, the processor 270 may provide the illumination function based on the user input.

In addition, the user interface 230 may receive the user input by using a non-contact method. In a case of receiving the user input by using a contact method, a physical force may be required to be transmitted to the electronic apparatus 100. There may thus be a need for a method of controlling the electronic apparatus 100 regardless of the physical force. The user interface 230 may receive a user gesture and may perform an operation corresponding to the received user gesture. The user interface 230 may receive the user gesture through a sensor (e.g., image sensor and/or infrared sensor).

In addition, the user interface 230 may receive the user input by using a touch method. For example, the user interface 230 may receive the user input through a touch sensor. For another example, the touch method may be implemented as the non-contact method. That is, the touch sensor may determine whether a user body approaches within a critical distance. In an embodiment, the touch sensor may identify the user input even in a case in which the user does not touch the touch sensor. In an example, the touch sensor may identify the user input when the user touches the touch sensor.

The electronic apparatus 100 may receive the user input in various ways other than the user interface described above. For example, the electronic apparatus 100 may receive the user input from an external remote control device. The external remote control device may be a remote control device corresponding to the electronic apparatus 100 (e.g., control device dedicated to the electronic apparatus 100) and/or a portable communication device (e.g., smartphone and/or wearable device) of the user. The portable communication device of the user may store an application for controlling the electronic apparatus 100. The portable communication device may obtain the user input from the application stored therein, and transmit the obtained user input to the electronic apparatus 100. The electronic apparatus 100 may receive the user input from the portable communication device, and perform an operation corresponding to the user's control command

The electronic apparatus 100 may receive the user input by using voice recognition. For example, the electronic apparatus 100 may receive a user voice through the microphone included in the electronic apparatus 100. In an example, the electronic apparatus 100 may receive the user voice from the microphone and/or the external device. In such an example, the external device may obtain the user voice through a microphone of the external device, and may transmit the obtained user voice to the electronic apparatus 100. The user voice transmitted from the external device may be audio data and/or digital data converted from the audio data (e.g., audio data converted to a frequency domain). In an embodiment, the electronic apparatus 100 may perform an operation corresponding to the received user voice. For example, the electronic apparatus 100 may receive the audio data corresponding to the user voice through the microphone. The electronic apparatus 100 may then convert the received audio data to the digital data. The electronic apparatus 100 may then convert the converted digital data to text data by using a speech-to-text (STT) function. For example, the speech-to-text (STT) function may be directly performed by the electronic apparatus 100.

Alternatively or additionally, the speech-to-text (STT) function may be performed by the external server. The electronic apparatus 100 may transmit the digital data to the external server. The external server may convert the digital data to the text data, and obtain control command data based on the converted text data. The external server may transmit the control command data (and/or the text data) to the electronic apparatus 100. The electronic apparatus 100 may perform an operation corresponding to the user voice based on the obtained control command data.

The electronic apparatus 100 may provide a voice recognition function by using a virtual assistant (and/or an artificial intelligence agent such as Bixby™), for example, and the electronic apparatus 100 may provide the voice recognition function by using a plurality of assistants. The electronic apparatus 100 may provide the voice recognition function by selecting one of the plurality of assistants based on a trigger word corresponding to the selected assistant and/or a specific key included in a remote controller.

The electronic apparatus 100 may receive the user input by using a screen interaction. The screen interaction may indicate a function in which the electronic apparatus 100 may identify whether a predetermined event is generated through the image projected to the screen (and/or a projection plane), and/or may obtain the user input based on the predetermined event. The predetermined event may be an event in which a predetermined object is identified at a specific position (e.g., position to which the UI for receiving the user input is projected). The predetermined object may include at least one of a user body part (e.g., finger), a pointer, and a laser point. The electronic apparatus 100 may identify that the electronic apparatus 100 receives the user input for selecting the projected UI in a case in which it is identified that the predetermined object exists at the position corresponding to the projected UI. For example, the electronic apparatus 100 may project a guide image displaying the UI on the screen. The electronic apparatus 100 may then identify whether the user selects the projected UI. The electronic apparatus 100 may identify that the user selects the projected UI in a case in which the predetermined event is identified at the position of the projected UI. The projected UI may include at least one item. For example, the electronic apparatus 100 may perform spatial analysis to identify whether the predetermined event exists at the position of the projected UI. The electronic apparatus 100 may perform the spatial analysis through the sensor (e.g., image sensor, infrared sensor, depth camera, or distance sensor). The electronic apparatus 100 may identify whether the predetermined event is generated at the specific position (e.g., position to which the UI is projected) by performing the spatial analysis. Alternatively or additionally, in a case in which it is identified that the predetermined event is generated at the specific position (e.g., position to which the UI is projected), the electronic apparatus 100 may identify that the electronic apparatus 100 receives the user input for selecting the UI corresponding to the specific position.

The input/output interface 240 may be and/or may include a component for inputting or outputting at least one of an audio signal or an image signal. The input/output interface 240 may receive at least one of the audio signal or the image signal from the external device, and output the control command to the external device.

The input/output interface 240 according to an embodiment of the disclosure may be implemented as a wired input/output interface of at least one of an HDMI), a mobile high-definition link (MHL), a USB (e.g., a USB C-type), a display port (DP), a Thunderbolt, a video graphics array (VGA) port, an RGB port, a D-subminiature (D-SUB), and a digital visual interface (DVI). For example, the wired input/output interface may be implemented as an interface inputting and/or outputting only the audio signal, as an interface inputting and/or outputting only the image signal, and/or as an interface inputting and/or outputting both the audio signal and the image signal.

In addition, the electronic apparatus 100 may receive the data through the wired input/output interface. For another example, the electronic apparatus 100 may receive power through the wired input/output interface. That is, the electronic apparatus 100 may receive power from an external battery through a USB C-type interface, and/or may receive power from an outlet through a power adapter. In an embodiment, the electronic apparatus 100 may receive power from the external device (e.g., laptop computer and/or monitor) through the DP interface.

The input/output interface 240, according to an embodiment of the disclosure, may be implemented as an wireless input/output interface that may perform the communication by using at least one communication method such as, but not limited to, Wi-Fi, Wi-Fi direct, Bluetooth™, ZigBee, Third Generation (3G), 3rd Generation Partnership Project (3GPP), Long Term Evolution (LTE), and the like. For example, the wireless input/output interface may be implemented as an interface inputting and/or outputting only the audio signal and another interface inputting and/or outputting only the image signal. Alternatively or additionally, the wireless input/output interface may be implemented as an interface inputting and/or outputting both the audio signal and the image signal.

In addition, the audio signal may be input through the wired input/output interface, and the image signal may be input through a wireless input/output interface. Alternatively or additionally, the audio signal may be input through the wireless input/output interface, and the image signal may be input through the wired input/output interface. However, the present disclosure is not limited in this regard.

The audio outputter 250 may be and/or may include a component that outputs the audio signal. For example, the audio outputter 250 may include an audio output mixer, an audio signal processor, and an audio output module. The audio output mixer may mix the plurality of audio signals to be output as at least one audio signal. For example, the audio output mixer may mix an analog audio signal and another analog audio signal (e.g., analog audio signal received from the outside) as at least one analog audio signal. The audio output module may include the speaker and/or an output terminal. According to an embodiment, the audio output module may include the plurality of speakers. In such an embodiment, the audio output module may be disposed in the main body, and audio emitted while covering at least a portion of a diaphragm of the audio output module may pass through a waveguide to be transmitted to the outside the main body. The audio output module may include a plurality of audio output units. In such an example, the plurality of audio output units may be symmetrically arranged on the exterior of the main body, and accordingly, the audio may be emitted in substantially all directions (e.g., all directions in 360 degrees, and/or omnidirectionally).

The power supply 260 may receive power from the outside and supply power to the various components of the electronic apparatus 100. The power supply 260, according to an embodiment of the disclosure, may receive power in various ways. For example, the power supply 260 may receive power by using the connector 130 as shown in FIG. 1. In addition, the electronic apparatus 100 may receive power by using a direct current (DC) power cord of 220V. However, the present disclosure is not limited thereto, and the power supply 260 may receive power by using a USB power cord, and/or may receive power by using a wireless charging method.

In addition, the power supply 260 may receive power by using an internal battery and/or the external battery. The power supply 260, according to an embodiment of the disclosure, may receive power through the internal battery. For example, the power supply 260 may charge power of the internal battery by using at least one of the DC power cord of 220V, the USB power cord, and a USB C-Type power cord, and/or the power supply 260 may receive power through the charged internal battery. Alternatively or additionally, the power supply 260, according to an embodiment of the disclosure, may receive power through the external battery. For example, the power supply 260 may receive power through the external battery in a case in which the electronic apparatus 100 and the external battery are connected through various wired communication methods such as, but not limited to, the USB power cord, the USB C-type power cord, and/or a socket groove. That is, the power supply 260 may directly receive power from the external battery, and/or charge the internal battery through the external battery and receive power from the charged internal battery.

The power supply 260, according to the present disclosure, may receive power by using at least one of the aforementioned power supply methods.

With respect to power consumption, the electronic apparatus 100 may have the power consumption of a predetermined value (e.g., 43 Watts (W)) or less due to a socket type, another standard, and the like. The electronic apparatus 100 may change power consumption to reduce the power consumption when using the battery. That is, the electronic apparatus 100 may change the power consumption based on the power supply method, power usage amount, and the like.

The electronic apparatus 100, according to an embodiment of the disclosure, may provide various smart functions.

The electronic apparatus 100 may be connected to a portable terminal device controlling the electronic apparatus 100, and the screen output from the electronic apparatus 100 may be controlled by the user input which is input from the portable terminal device. For example, when the portable terminal device is implemented as a smartphone including a touch display, the electronic apparatus 100 may receive screen data provided by the portable terminal device from the portable terminal device and output the data, and the screen output by the electronic apparatus 100 may be controlled based on the user input that is input from the portable terminal device.

The electronic apparatus 100 may be connected to the portable terminal device by using various communication methods such as, but not limited to, Miracast™, AirPlay™, wireless Dalvik executable (DEX), a remote personal computer (PC) method, and the like. The electronic apparatus 100 may share a content or music, provided by the portable terminal device.

In addition, the portable terminal device and the electronic apparatus 100 may be connected to each other by various connection methods. For example, the portable terminal device may search for the electronic apparatus 100 and perform wireless connection therebetween, or the electronic apparatus 100 may search for the portable terminal device and perform the wireless connection therebetween. The electronic apparatus 100 may then output the content provided from the portable terminal device.

For example, the electronic apparatus 100 may output the content and/or music being output from the portable terminal device in a case in which the portable terminal device is positioned around the electronic apparatus 100 and the predetermined gesture (e.g., motion tap view) is then detected through the display of the portable terminal device, while the specific content or music is being output from the portable terminal device.

For example, the electronic apparatus 100 may output the content or music being output from the portable terminal device in a case in which it is detected that the portable terminal device is positioned around the electronic apparatus 100 by a predetermined distance or less (e.g., non-contact tap view), and/or the portable terminal device touches the electronic apparatus 100 twice at short intervals (e.g., contact tap view) in the state where the specific content or music is being output from the portable terminal device.

In the above example, the screen provided by the portable terminal device is the same as the screen provided by the electronic apparatus 100. However, the disclosure is not limited thereto. That is, in a case in which the portable terminal device and the electronic apparatus 100 are connected to each other, the portable terminal device may output a first screen provided by the portable terminal device, and the electronic apparatus 100 may output a second screen provided by the portable terminal device, which may be different from the first screen. For example, the first screen may be a screen provided by a first application installed in the portable terminal device, and the second screen may be a screen provided by a second application installed in the portable terminal device. For another example, the first screen and the second screen may be different screens from each other that may be provided by one application installed in the portable terminal device. In addition, for example, the first screen may be a screen including the UI in a remote controller form for controlling the second screen.

The electronic apparatus 100, according to the disclosure, may output a standby screen. For example, the electronic apparatus 100 may output the standby screen in a case in which the electronic apparatus 100 and the external device are not connected to each other and/or in a case in which there is no input received from the external device for the predetermined time. A condition for the electronic apparatus 100 to output the standby screen may not be limited to the above-described example, and the standby screen may be output based on various conditions.

The electronic apparatus 100 may output the standby screen in the form of a blue screen. However, the present disclosure is not limited thereto. For example, the electronic apparatus 100 may obtain an atypical object by extracting only the shape of a specific object from the data received from the external device, and output the standby screen including the obtained atypical object.

FIG. 3 is a perspective view illustrating the exterior of the electronic apparatus 100, according to an embodiment of the disclosure.

Referring to FIG. 3, the electronic apparatus 100 may include a support 108a (and/or a handle).

The support 108a may be and/or may include a handle and/or a ring that may be provided for the user to grip and/or move the electronic apparatus 100. Alternatively or additionally, the support 108a may be a stand that may support the main body 105 while the main body 105 is laid sideways.

As shown in FIG. 3, the support 108a may have a hinge structure for the support to be coupled to and/or separated from an outer circumferential surface of the main body 105, and may be selectively separated from and/or fixed to the outer circumferential surface of the main body 105 based on the user's need. The number, shape, or disposition structure of the support 108a may be implemented in various ways without restriction. Although it is not described in the drawing, the support 108a may be built in the main body 105, and taken out and used by the user based on the user need. Alternatively, the support 108a may be implemented as a separate accessory, and attached to or detached from the electronic apparatus 100.

The support 108a may include a first support surface 108a-1 and a second support surface 108a-2. The first support surface 108a-1 may be a surface that faces the outside of the main body 105 while the support 108a is separated from the outer circumferential surface of the main body 105. The second support surface 108a-2 may be a surface that faces the inside of the main body 105 while the support 108a is separated from the outer circumferential surface of the main body 105.

The first support surface 108a-1 may be developed from the lower portion to upper portion of the main body 105 to be farther away from the main body 105. The first support surface 108a-1 may have a flat and/or uniformly curved shape. The first support surface 108a-1 may support the main body 105 in a case in which the electronic apparatus 100 is held in such a manner that the outer side surface of the main body 105 is in contact with the bottom (e.g., in a case in which the electronic apparatus 100 is disposed in such a manner that the projection lens 110 is toward the front). For example, if the electronic apparatus 100 includes two or more supports 108a, the head 103 and the projection angle of the projection lens 110 may be adjusted by adjusting the interval or hinge opening angle of the two supports 108a.

Alternatively or additionally, the second support surface 108a-2 may be and/or may include a surface touched by the user and/or an external holding structure in a case in which the support 108a is supported by the user and/or the external holding structure. The second support surface 108a-2 may have a shape corresponding to a gripping structure of the user's hand and/or the external holding structure for the electronic apparatus 100 so as to minimize a probability of slipping in a case in which the electronic apparatus 100 is supported and/or moved by the second support surface 108a-2. For example, the user may move the electronic apparatus 100 by making the projection lens 110 face toward the front, fixing the head 103 and holding the support 108a, and/or use the electronic apparatus 100 like a flashlight.

The support groove 104 may be a groove structure which may be provided in the main body 105 and may accommodate the support 108a in a case in which the support 108a is not used. As shown in FIG. 3, the support groove 104 may be implemented as a groove structure corresponding to the shape of the support 108a in the outer circumferential surface of the main body 105. By using the support groove 104, the support 108a may be stored on the outer circumferential surface of the main body 105 in a case in which the support 108a is not used, and the outer circumferential surface of the main body 105 may be maintained to be slick.

Alternatively, the support 108a may be stored inside the main body 105, and may be taken out to the outside of the main body 105 in a case in which the support 108a is needed. In such an embodiment, the support groove 104 may be led into the inside of the main body 105 to accommodate the support 108a, and the second support surface 108a-2 may have a door that may adhere to the outer circumferential surface of the main body 105 and/or may open and/or close the separate support groove 104.

In an optional or additional embodiment, the electronic apparatus 100 may include various kinds of accessories that may provide assistance in using and/or storing the electronic apparatus 100. For example, the electronic apparatus 100 may include a protection case for the electronic apparatus 100 that may allow the electronic apparatus 100 to be carried while being protected. Alternatively, the electronic apparatus 100 may include a tripod that may support and/or fix the main body 105. For another example, the electronic apparatus 100 may include a bracket that may be coupled to the outer surface of the electronic apparatus 100 and fix the electronic apparatus 100.

FIG. 4 is a perspective view illustrating the exterior of the electronic apparatus 100, according to an embodiment of the disclosure.

Referring to FIG. 4, the electronic apparatus 100 may include a support 100B (and/or a handle).

The support 108b may be and/or may include the handle or the ring that may be provided for the user to grip and/or move the electronic apparatus 100. Alternatively or additionally, the support 108b may be the stand that supports the main body 105 to be oriented at any angle while the main body 105 is laid sideways.

As shown in FIG. 4, the support 108b may be connected with the main body 105 at a predetermined point of the main body 105 (e.g., at a point corresponding to between ⅔ and ¾ of a height of the main body 105). In a case in which the support 108 is rotated toward the main body, the support 108b may support the main body 105 for the main body 105 to be oriented at any angle while the main body 105 is laid sideways.

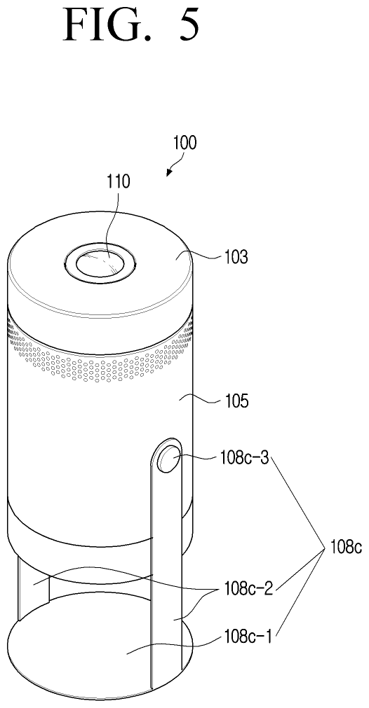

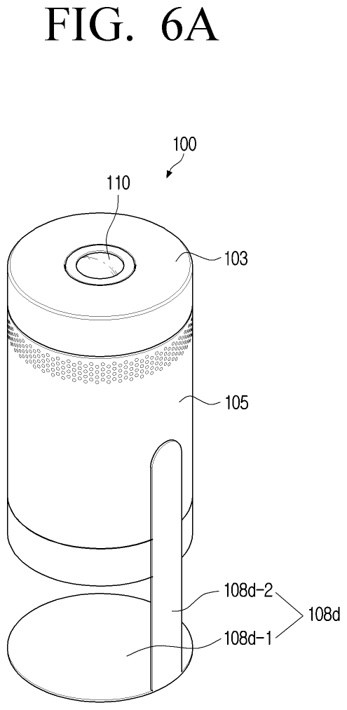

FIG. 5 is a perspective view illustrating the exterior of the electronic apparatus 100, according to an embodiment of the disclosure.

Referring to FIG. 5, the electronic apparatus 100 may include a support 108c (and/or a handle). The support 108c may be and/or may include a base plate 108c-1 supporting the electronic apparatus 100 on the ground and two support members 108c-2 connecting the base plate 108c-1 with the main body 105.

In an embodiment, the two support members 108c-2 may have the same height, and a cross section of each of the two support members 108c-2 may be coupled to and/or separated from each other by a groove and a hinge member 108c-3 provided on one outer circumferential surface of the main body 105.

The two support members may be hinge-coupled to the main body 105 at a predetermined point of the main body 105 (e.g., at a point corresponding to between ⅓ and ½ of the height of the main body 105).

In a case in which the two support members and the main body are coupled with each other by the hinge member 108c-3, the main body 105 may be rotated based on a virtual horizontal axis formed by the two hinge members 108c-3, thus adjusting the projection angle of the projection lens 110.

FIG. 5 illustrates an example in which the two support members 108c-2 are connected with the main body 105, however, the present disclosure is not limited thereto. For example, as shown in FIGS. 6A and 6B, one support member and the main body 105 may be connected with each other by one hinge member.

FIGS. 6A and 6B are perspective views illustrating the exterior of the electronic apparatus 100, according to an embodiment of the disclosure.

Referring to FIGS. 6A and 6B, a support 108d may include a base plate 108d-1 supporting the electronic apparatus 100 on the ground and one support member 108d-2 connecting a base plate 108d-1 with the main body 105.

In addition, a cross section of the one support member 108d-2 may be coupled to and/or separated from the main body by a groove and a hinge member provided on one outer circumferential surface of the main body 105.

In a case in which the one support member 108d-2 and the main body 105 are coupled with each other by one hinge member, the main body 105 may be rotated based on a virtual horizontal axis formed by the one hinge member, as in FIG. 6B.

The supports illustrated in FIGS. 3, 4, 5, 6A, and 6B are only an example, and the electronic apparatus 100 may include supports in various positions and/or shapes.

Having described various examples of an exterior and configuration of an electronic apparatus 100, a power supply of an electronic apparatus 100 is described below.

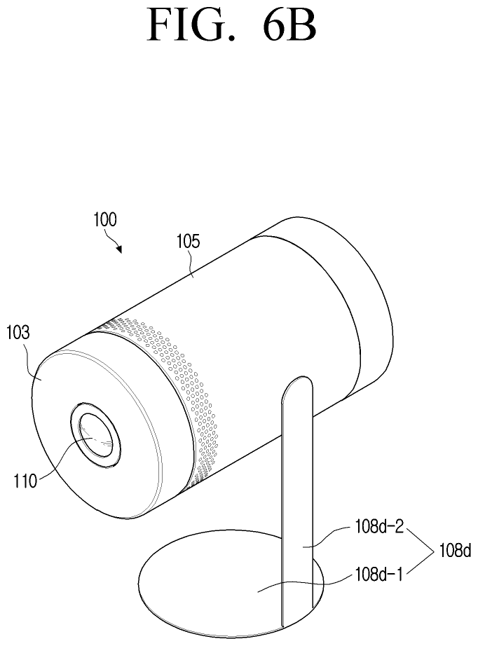

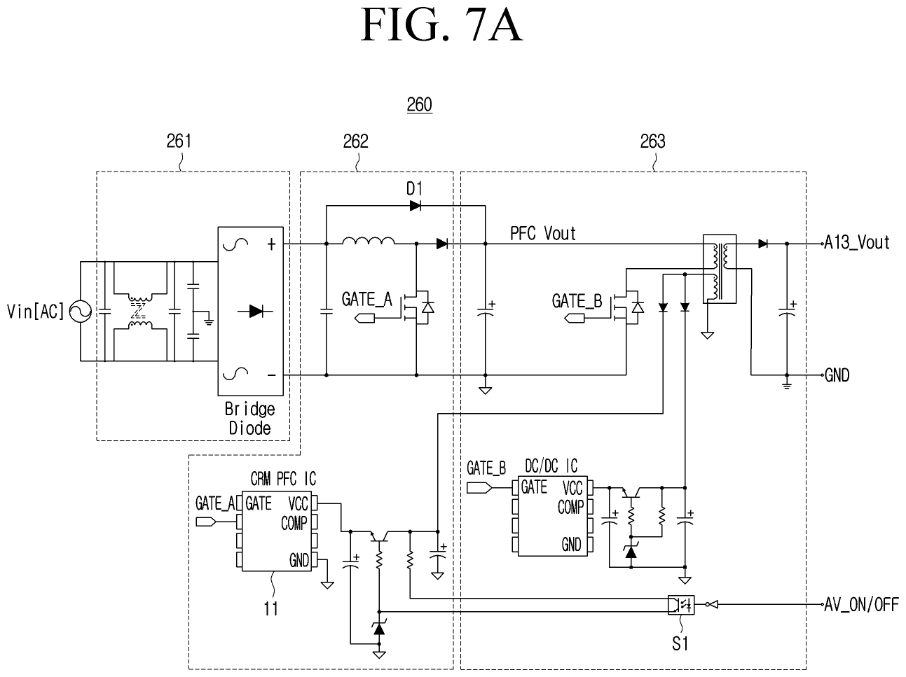

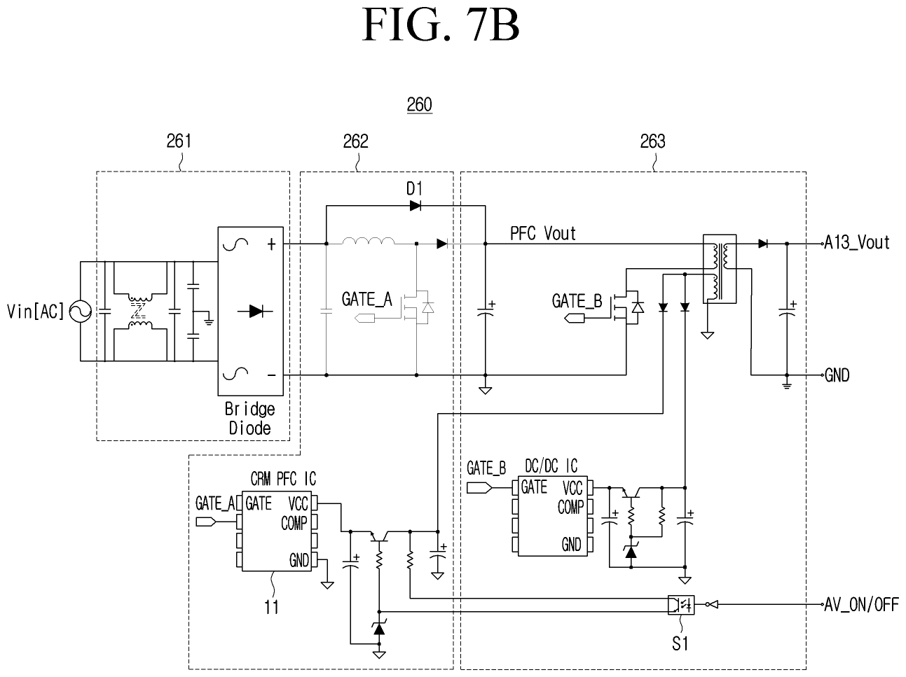

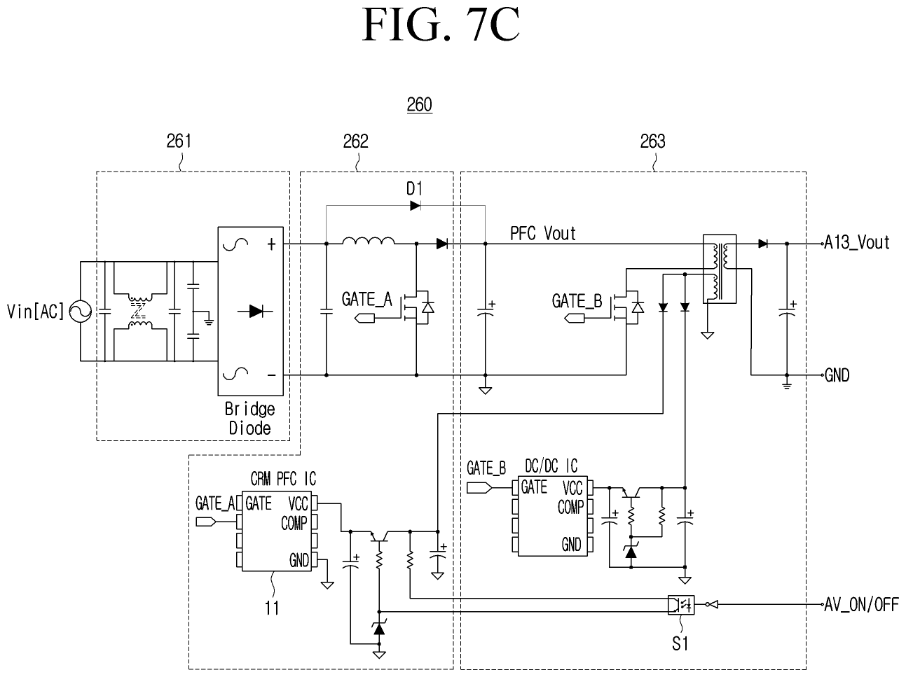

FIG. 7A is a diagram illustrating a power supply of an electronic apparatus 100 for control of a power factor correction (PFC) control circuit according to a function performed, according to an embodiment of the disclosure.

Referring to FIG. 7A, a power supply (e.g., a switching mode power supply (SMPS)) 260 of an electronic apparatus 100 may include a transformation part 261, a PFC part 262, and a converter part 263.

The transformation part 261 may convert alternating current (AC) power input from the outside into DC power. Examples of the transformation part 261 may include a step-down transformer, a rectifier, a filter, and the like. The step-down transformer may reduce an AC voltage input from the outside. The rectifier may be implemented as a bridge circuit, and may convert the reduced AC voltage to a DC voltage. The filter may remove a ripple of the DC voltage to generate a DC voltage of a certain level. The DC voltage obtained by conversion by the transformation part 261 may be transmitted to the PFC part 262.

The PFC part 262 may perform a PFC function to satisfy the THD standard under certain conditions. The PFC part 262 may include a PFC circuit (GATE_A region) that may perform the PFC function, and a PFC control circuit (or a PFC control integrated circuit (IC)) 11 that may control the PFC circuit. When power is supplied to the PFC control circuit 11, the PFC control circuit 11 may control the GATE_A so that the PFC circuit may perform the PFC function. When power is not supplied to the PFC control circuit 11, the PFC control circuit 11 may not control the GATE_A and the PFC circuit may not perform the PFC function. The DC power passing through the PFC part 262 may be transmitted to the converter part 263.

The converter part 263 may boost the DC power transmitted from the PFC part 262 and output the boosted DC power through an output terminal thereof. The converter part 263 may include a transformer, a first switch S1, and the output terminal A13_Vout. For example, the transformer of the converter part 263 may boost the transmitted DC power, and output the boosted DC power through the output terminal. The DC power output from the converter part 263 may be supplied to each component of the electronic apparatus 100.

As described above, an electronic apparatus 100 may perform a multimedia function and/or a lighting function. For example, when the electronic apparatus 100 performs the lighting function, the corresponding THD standard may be satisfied and thus the PFC part 262 may perform the PFC function. When the electronic apparatus 100 performs the multimedia function, the corresponding THD standard may not be applied thereto, and thus, the PFC part 262 may not perform the PFC function. The first switch S1 of the converter part 263 may control power to be supplied to the PFC control circuit 11. The first switch S1 may be turned on and/or off by a multimedia on/off signal AV_ON/OFF. In an embodiment, when the first switch S1 is connected to a NOT gate, the first switch S1 may be turned on by a multimedia OFF (e.g., a LOW) signal. When a signal of the multimedia function is input to the first switch S1 without the NOT gate, the first switch S1 may be turned on by a multimedia ON (e.g., a HIGH) signal.

For example, the first switch S1 may be connected in parallel between a power terminal of the PFC control circuit 11 and the ground, and may include a photocoupler. When the first switch S1 is off, the power terminal of the PFC control circuit 11 and the ground may be short-circuited, and thus, power may be supplied to the PFC control circuit 11 and the PFC control circuit 11 may control the PFC circuit. When the first switch S1 is on, the power terminal of the PFC control circuit 11 and the ground may be disconnected from each other, and thus, the supply of power to the PFC control circuit 11 may be cut off. The PFC control circuit 11 may not control the PFC circuit because power may not be supplied to the PFC control circuit 11. That is, the first switch S1 of the converter part 263 may be turned on when a multimedia mode is selected (e.g., when the electronic apparatus 100 performs the multimedia function), and may be turned off when a lighting mode is selected (e.g., when the electronic apparatus 100 performs the lighting function). Alternatively or additionally, the PFC part 262 may control the PFC control circuit 11 and the PFC circuit on the basis of a state of the first switch S1. An operation of an electronic apparatus 100 in the multimedia mode and an operation of the electronic apparatus 100 in the lighting mode is described in detail below.

FIG. 7B is a diagram for describing operations of an electronic apparatus 100 when the multimedia function is performed, according to an embodiment of the disclosure.

Referring to FIG. 7B, a multimedia signal AV_ON/OFF may be low as the electronic apparatus 100 performs the multimedia function. The multimedia signal AV_ON/OFF that is low may be output as high through a NOT gate. Consequently, the first switch S1 may be turned on by the multimedia signal that is output as high. As described above, when an electronic apparatus 100 that does not include the NOT gate performs the multimedia function, a multimedia signal AV_ON/OFF may be high and the first switch S1 may be turned on by the multimedia signal AV_ON/OFF that is high.

When the first switch S1 is on, a closed circuit may be formed between a power terminal of a PFC control circuit and the ground. Accordingly, power supplied to the PFC control circuit may be cut off. As the power input to the PFC control circuit is cut off, the operation of the PFC control circuit may be stopped and the operation of the PFC circuit may be also stopped. When the operation of the PFC circuit is stopped, a power factor (PF) may decrease and a THD rate may increase. In an embodiment, as shown in FIG. 7B, the PFC part 262 may include a bypass circuit (region D1) bypassing the PFC circuit. The power transmitted from the transformation part 261 may be transferred to the converter part 263 through the bypass circuit as the operation of the PFC circuit is stopped.

FIG. 7C is a diagram for describing operations of an electronic apparatus 100 when a lighting function is performed, according to an embodiment of the disclosure.

Referring to FIG. 7C, a multimedia signal AV_ON/OFF may be high as the electronic apparatus 100 performs the lighting function. The multimedia signal AV_ON/OFF that is high may be output as low through a NOT gate. The first switch S1 may be turned off by the multimedia signal AV_ON/OFF that is output as low. As described above, when an electronic apparatus 100 that does not include the NOT gate performs the lighting function, a multimedia signal AV_ON/OFF may be low and the first switch S1 may be turned off by the multimedia signal AV_ON/OFF that is low.

When the first switch S1 is off, an open circuit may be formed between the power terminal of the PFC control circuit and the ground. Therefore, power may be supplied to the PFC control circuit. As power is supplied to the PFC control circuit, the PFC control circuit may control the PFC circuit and the PFC circuit may operate. When the PFC circuit operates, a PF may increase and a THD rate may decrease, and thus, the electronic apparatus 100 may meet a THD requirement of lighting standards. The power output from the PFC part may be transmitted to the converter part 263 and output through an output terminal Al3_Vout.

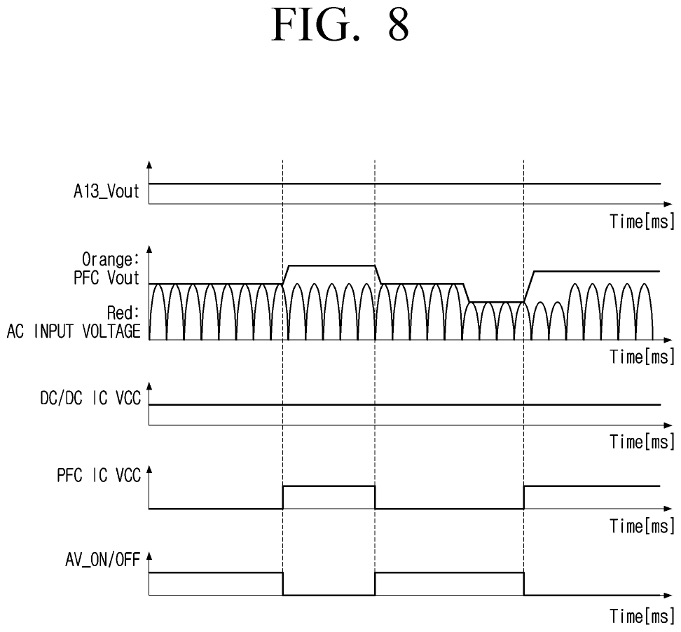

FIG. 8 is a diagram illustrating an operation waveform of the electronic apparatus 100 of FIG. 7A according to an embodiment of the disclosure.

Referring to FIG. 8, a multimedia signal AV_ON/OFF may be maintained as high and/or low according to the multimedia mode and/or the lighting mode. When the electronic apparatus 100 is in the multimedia mode (e.g., in which either the multimedia function and/or both the multimedia function and the lighting simultaneous are used), the multimedia signal AV_ON/OFF may be maintained as high. When the electronic apparatus 100 is in the lighting mode (e.g., in which only the lighting function is used), the multimedia signal AV_ON/OFF may be maintained as low. Whether to supply power to the PFC control circuit may be determined according to the multimedia signal AV_ON/OFF. When the multimedia signal AV_ON/OFF is high, the supply of power to the PFC control circuit may be stopped and the operation of the PFC part (and/or the PFC circuit) may also be stopped. When the multimedia signal AV_ON/OFF is low, power may be supplied to the PFC control circuit to operate the PFC part (and/or the PFC circuit). For example, PFC Vout may be maintained between 390 and 400 Volts (V) when the PFC part is operated, and may vary according to a peak voltage of an input voltage Vin when the operation of the PFC part is stopped. The PFC voltage may be set to be higher than an AC power level, so that power may be transmitted to a converter part through the PFC part rather than the bypass circuit (region D1) when the PFC part is operated, thereby improving a PF and a THD rate.

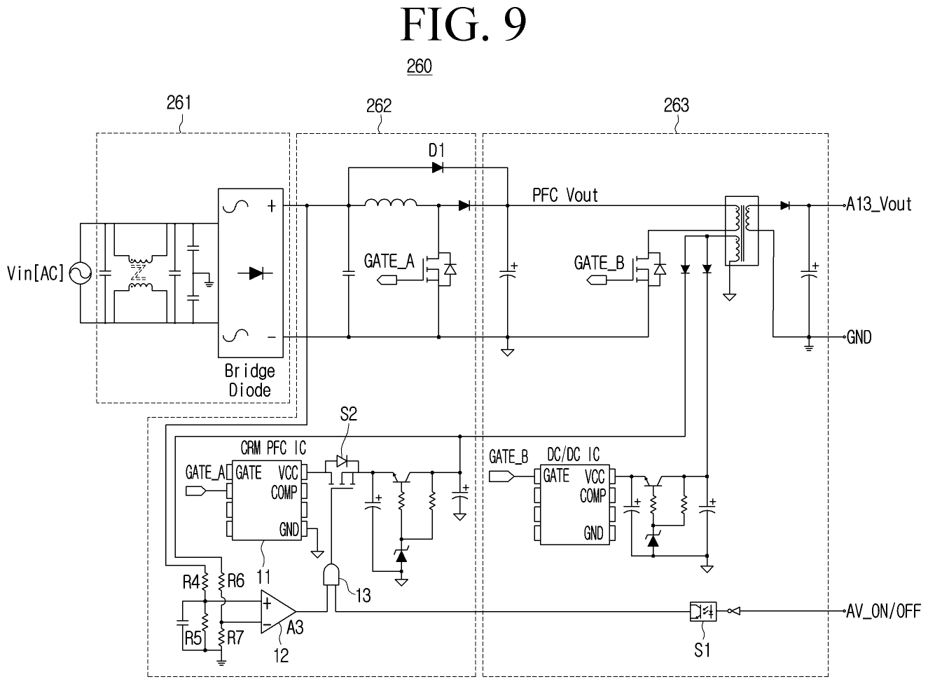

FIG. 9 is a diagram illustrating a power supply of an electronic apparatus 100 for control of a PFC control circuit according to a function to be performed and an input voltage, according to an embodiment of the disclosure.

Referring to FIG. 9, a power supply 260 of the electronic apparatus 100 may further include a first comparator 12, an AND gate 13, and a second switch S2. The electronic apparatus 100 may further include the first comparator 12, the AND gate 13, and the second switch S2 to control an on/off operation of the PFC part 262 according to an input voltage.

The second switch S2 may be connected to the power terminal of the PFC control circuit 11 and controlled according to an output signal of the AND gate 13. An input terminal of the AND gate 13 may be connected to an output terminal of the first comparator 12 and one terminal of the first switch S1. Another terminal of the first switch S1 may be connected to the ground.

A peak value of an input voltage may be detected by resistors R4 and R5 connected to the input terminal of the first comparator 12. Resistors R6 and R7 may be connected to a fixed DC power source, and a voltage at a negative terminal of the first comparator 12 may be a fixed DC voltage level. Accordingly, the voltage of the negative terminal of the first comparator 12 may be referred to as a reference voltage. An output of the first comparator 12 may be high when a positive input of the first comparator 12 is greater than a negative input, and may be low when the positive input of the first comparator 12 is less than the negative input. The output of the first comparator 12 and the multimedia signal AV_ON/OFF may be input to the AND gate 13. An output of the AND gate 13 may control the second switch S2 between the power terminal of the PFC control circuit 11 and a power line. That is, when the lighting mode is selected, the first switch S1 may be turned off by the multimedia signal AV_ON/OFF. When the first switch S1 is in the off state, an input of the AND gate 13 connected to a multimedia signal side may be a high signal. The first comparator 12 may output a high signal when the DC voltage is greater than or equal to a preset reference voltage. The AND gate 13 may output a high signal according to a high signal output from the first comparator 12 and a high signal at the multimedia signal side. The high signal output from the AND gate 13 may turn on the second switch S2, and power may be supplied to the PFC control circuit 11. When the power is supplied to the PFC control circuit 11, the PFC control circuit 11 may operate the PFC circuit, and the DC power obtained by conversion by the transformation part 261 may be transmitted to the converter part 263 through the PFC circuit.

When the first switch S1 is on, the AND gate 13 may output a low-level signal when the signal at the multimedia signal side is low or the output of the first comparator 12 is low. The low-level signal output from the AND gate 13 may turn off the second switch S2, and the supply of power to the PFC control circuit 11 may be cut off. That is, the PFC part 262 may operate based on the supplied power being greater than or equal to a preset value and based on the electronic apparatus 100 performing the lighting mode.

For example, when power consumption of the electronic apparatus 100 is 5 W, a lighting device (and/or an electronic apparatus 100 including the lighting function) may satisfy a THD standard in a first region (e.g., when used in at least a portion of Europe). However, there may be no THD standards for a lighting device (and/or an electronic apparatus 100 including the lighting function), such as, but not including, the United States of America. Therefore, the electronic apparatus 100 may operate the PFC part 262 when an input voltage is 230 Vac in an European area, and turn off the PFC part 262 when an input voltage is in a range of 110 to 120 Vac in an area of the United States. According to an input voltage, the efficiency of the PFC part 262 may vary, and as a result, a difference in temperature between components thereof may occur. Since the temperature of the components of the power supply (e.g., SMPS) 260 is related to the lifespan of the power supply 260, the power supply 260 may be designed to have a lifespan matching that of the electronic apparatus 100. A temperature of the PFC part 262 when an input voltage is low may be higher than when the input voltage is high. The amount of current flowing through the PFC part 262 when an input voltage is 220 Vac may be half the amount of current flowing through the PFC part 262 when the input voltage is 110 Vac. Consequently, a PFC rated power design value when an input voltage is 110 Vac may be double that when the input voltage is 220 Vac. For example, when the rated power of the PFC part 262 that may be optimized for an input voltage of 220 Vac is 20 W, the amount of power that may be supplied from the PFC part 262 when an input voltage is 110 Vac may only be 10 W, that is, half of 20 W. As a result, in the embodiment of FIG. 7, the rated power design value of the PFC part 262 may be reduced by half, and the size and costs of the PFC part 262 may be reduced.

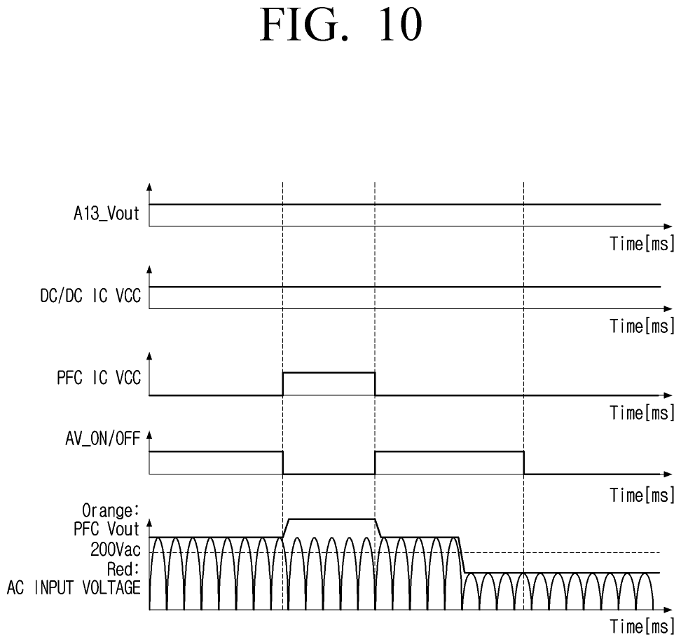

FIG. 10 is a diagram illustrating an operation waveform of the electronic apparatus 100 of FIG. 9, according to an embodiment of the disclosure.

Referring to FIG. 10, a reference value of an AC input voltage for operation of the PFC part may be set to 200 Vac in consideration of an operation margin. When the AC input voltage is 200 Vac or higher and a multimedia signal AV_ON/OFF is low, power may be supplied to the PFC control circuit and the PFC part may operate.

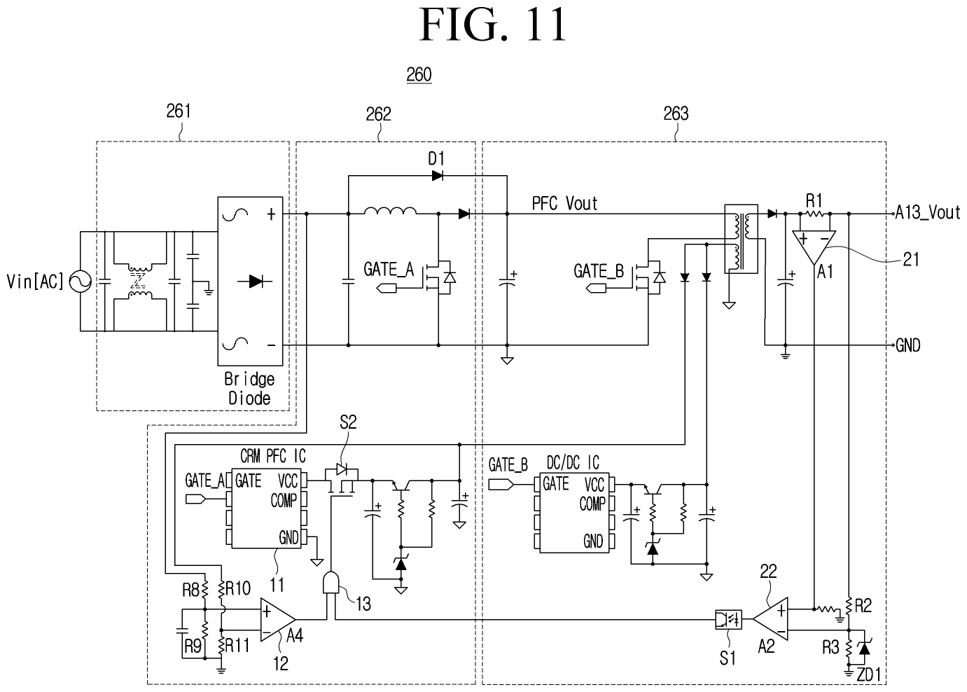

FIG. 11 is a diagram illustrating an electronic apparatus 100 with a power supply embodied as an adapter according to an embodiment of the disclosure.

Referring to FIG. 11, a power supply 260 of the electronic apparatus 100 may include a transformation part 261, a PFC part 262, and a converter part 263. The PFC part 262 may include a PFC circuit, a PFC control circuit 11, a first comparator 12, an AND gate 13, and a second switch S2. The converter part 263 may include a transformer, a first switch S1, an output current monitoring circuit, and an output terminal. The operations of the transformation part 261, the PFC part 262, and the converter part 263 of FIG. 11 may substantially similar and/or may be the same as those of the transformation part 261, the PFC part 262, and the converter part 263 described with reference to FIGS. 7A to 7C and 9, and thus, redundant descriptions may be omitted for the sake of brevity.

When the electronic apparatus 100 is implemented as a DC adapter, the DC adapter may include only a DC output terminal and a GND-2 pin and thus may not receive a signal for converting a mode of the power supply 260. Thus, the output current monitoring circuit may monitor a DC output current and control the turning on/off of the PFC part 262. When output current flows through a resistor R1, a voltage applied to both ends of the resistor R1 may be amplified by the output current monitoring circuit. For example, the output current monitoring circuit may include an amplifier 21 and a second comparator 22. When a value of the resistor R1 is large, power loss may increase. Accordingly, the output current monitoring circuit may include the amplifier 21 to reduce the value of the resistor R1. The output current monitoring circuit may detect an output voltage by using resistors R2 and R3. The detected output voltage may be applied to a positive terminal of the second comparator 22, and an output voltage of the amplifier 21 may be applied to a negative terminal of the second comparator 22. A Zener diode ZD1 may prevent voltages at both ends of the resistor R3 from increasing to a certain voltage or more. Therefore, an output of the second comparator 22 may be high when an output current is less a preset value, and may be low when the output current is greater than or equal to a preset value. The output of the second comparator 22 may be input to an AND gate 13 of the PFC part 262, and the AND gate 13 may output a low-level signal or a high signal according to an output of the first comparator 12 and the output of the second comparator 22. That is, the PFC part 262 may operate when an input voltage is greater than or equal to a preset value and an output current is less than or equal to the preset value.

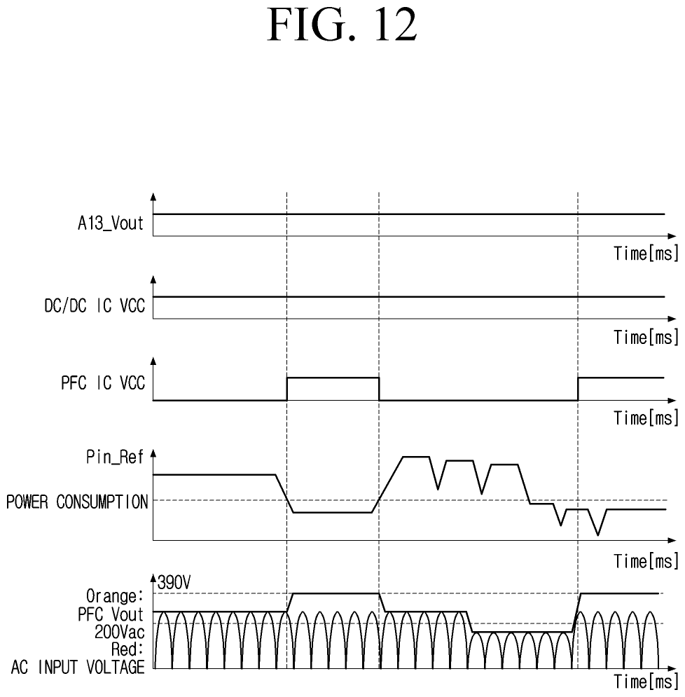

FIG. 12 is a diagram illustrating an operation waveform of the electronic apparatus 100 of FIG. 11, according to an embodiment of the disclosure.

Referring to FIG. 12, power may be supplied to the PFC control circuit and the PFC part may operate only when power consumption is less than Pin_Ref and an AC input voltage is higher than 200 Vac. In other situations, the supply of power to the PFC control circuit may be cut off, and thus, the PFC part may not operate. Therefore, the PFC part may not operate in areas in which an AC input voltage is in a range of 110 to 120 Vac (e.g., areas of the U.S.A.), and may operate in areas in which an AC input voltage is in a range of 220 to 230 Vac (e.g., European areas) when power consumption is less than Pin_Ref. Accordingly, as shown in FIG. 10, a rated power design value of the PFC part may be reduced, and as a result, the size of a power supply may be reduced.

Having described various embodiments of a power supply of an electronic apparatus 100, a control method is described below.

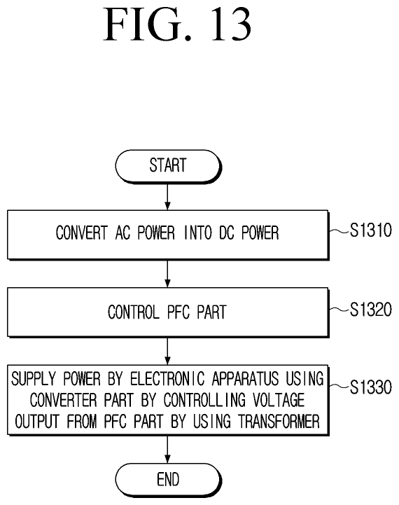

FIG. 13 is a flowchart of a control method of an electronic apparatus 100, according to an embodiment of the disclosure.

Referring to FIG. 13, the electronic apparatus 100 may convert AC power into DC power (operation S1310).

The electronic apparatus 100 may control a PFC part (operation S1320). When the multimedia mode is selected, the electronic apparatus 100 may turn on a first switch included in a converter part. Alternatively, the electronic apparatus 100 may turn off the first switch when the lighting mode is selected. The electronic apparatus 100 may control a PFC control circuit of the PFC part on the basis of a state of the first switch. For example, when the multimedia mode is selected, the electronic apparatus 100 may cut off the supply of power to the PFC control circuit on the basis of an on-state of the first switch. The electronic apparatus 100 transmit the converted DC power to the converter part through the bypass circuit by cutting off the supply of power to the PFC control circuit to stop the operation of the PFC circuit. When the lighting mode is selected, the electronic apparatus 100 may supply power to the PFC control circuit on the basis of an off-state of the first switch. The electronic apparatus 100 may operate the PFC circuit by the power supplied to the PFC control circuit to transmit the DC power to the converter part through the PFC circuit.

Alternatively, the electronic apparatus 100 may output a first high signal when a DC voltage of the converted DC power is greater than or equal to a preset reference voltage. When the lighting mode is selected, the electronic apparatus 100 may output a second high signal on the basis of an off-state of the first switch. The electronic apparatus 100 may output a third high signal on the basis of the first and second high signals. The electronic apparatus 100 may turn on a second switch on the basis of the output third-level high signal, and supply power to the PFC control circuit on the basis of an on-state of the second switch. The electronic apparatus 100 may operate the PFC circuit by the power supplied to the PFC control circuit to transmit the DC power to the converter part through the PFC circuit.

The electronic apparatus 100 controls a voltage output from the PFC part to supply power (operation S1330).

The control methods of an electronic apparatus 100, according to the various embodiments described above, may be provided through a computer program product. A computer program product may include a software (S/W) program and/or a non-transitory computer readable medium storing the S/W program.

The non-transitory computer readable medium may be understood to refer to a medium that may store data semi-permanently and that may be readable by a machine rather than a medium (e.g., a register, a cache or a memory), that stores data for a short time. For example, various applications and/or programs as described above may be stored in a non-transitory computer readable medium such as, but not limited to, a compact disc (CD), a digital versatile disc (DVD), a hard disk, a Blu-ray disk, a USB, a memory card, a ROM, and the like.

While embodiments of the disclosure have been illustrated and described herein, the disclosure is not limited thereto and various modifications may be made therein by those of ordinary skill in the art without departing from the scope of the disclosure as claimed in the accompanying claims. These modifications may not be understood separately from the scope and spirit of the disclosure.

What is claimed is:

1. An electronic apparatus comprising:
a transformation part configured to convert alternating current (AC) power into direct current (DC) power;
a power factor correction (PFC) part comprising a PFC circuit and a PFC control circuit; and
a converter part configured to:
control a voltage output from the PFC part by using a transformer to supply power through an output terminal of the converter part;
set a first switch of the converter part to a first state based on the electronic apparatus performing a multimedia function; and
set the first switch to a second state based on the electronic apparatus performing a lighting function,
wherein the PFC part is configured to control the PFC control circuit, based on a state of the first switch.

2. The electronic apparatus of claim 1, wherein the first switch is coupled in parallel between a power terminal of the PFC control circuit and a ground voltage.

3. The electronic apparatus of claim 2, wherein the PFC part comprises a bypass circuit configured to bypass the PFC circuit, and
wherein the PFC part is further configured, based on the electronic apparatus performing the multimedia function, to:
cut off a supply of power to the PFC control circuit based on the first switch being on the first state, and
prevent the DC power to be transmitted by the PFC circuit to the converter part through the bypass circuit when the supply of power to the PFC control circuit is cut off.

4. The electronic apparatus of claim 2, wherein the PFC part is further configured, based on the electronic apparatus performing the lighting function, to:
supply the power to the PFC control circuit based on the first switch being on the second state; and
control the PFC control circuit to transmit the DC power to the converter part through the PFC circuit.

5. The electronic apparatus of claim 1, wherein the first switch comprises a photocoupler.

6. The electronic apparatus of claim 1, wherein the PFC part further comprises a comparator, an AND gate, and a second switch,
wherein the second switch is coupled to a power terminal of the PFC control circuit and is configured to be controlled by a signal output from the AND gate of the PFC part,
wherein an input terminal of the AND gate is coupled to an output terminal of the comparator and a first terminal of the first switch, and
wherein a second terminal of the first switch is coupled to a ground voltage.

7. The electronic apparatus of claim 6, wherein the PFC part is further configured, based on the electronic apparatus performing the lighting function, to:
set, using the AND gate, the second switch to the first state, based on a signal based on the second state of the first switch and a signal output from the comparator when the DC power is greater than or equal to a preset value;
supply the power to the PFC control circuit based on the first state of the second switch; and
operate the PFC circuit by using the power supplied to the PFC control circuit to transmit the DC power to the converter part through the PFC circuit.

8. An electronic apparatus comprising:
a transformation part configured to convert alternating current (AC) power into direct current (DC) power;
a power factor correction (PFC) part comprising a PFC circuit, a PFC control circuit, a first comparator, an AND gate, and a second switch; and
a converter part comprising a first switch and an output current monitoring circuit,
wherein the second switch is coupled to a power terminal of the PFC control circuit and is configured to be controlled by a signal output from the AND gate,
wherein an input terminal of the AND gate is coupled to an output terminal of the first comparator and a first terminal of the first switch,
wherein a second terminal of the first switch is coupled to a ground voltage,
wherein the converter part is configured to:
supply power through an output terminal of the converter part by controlling a first voltage output from the PFC part by using a transformer;
identify an output current of the power output through the output terminal of the converter part by using the output current monitoring circuit; and
control the first switch based on the identified output current, and
wherein the PFC part is configured to control power to be supplied to the PFC control circuit by controlling the second switch based on a state of the first switch and a signal output from the first comparator.

9. The electronic apparatus of claim 8, wherein the output current monitoring circuit comprises an amplifier and a second comparator,
wherein the amplifier comprises a first resistor coupled in parallel between input terminals of the amplifier,
wherein the amplifier is configured to control a voltage applied to the first resistor and transmit the voltage to the second comparator, and
wherein the second comparator is configured to output a signal in a second state, based on the output current being less than or equal to a preset value, according to the voltage transmitted from the amplifier and a sensed output voltage.

10. The electronic apparatus of claim 9, wherein the PFC part is further configured to:
control the power to be supplied to the PFC control circuit by controlling the second switch, based on a signal output from the first comparator and a signal output from the second comparator, based on the DC power being greater than or equal to a preset reference value.

11. A control method of an electronic apparatus, the control comprising:
converting alternating current (AC) power into direct current (DC) power;
controlling a power factor corrector (PFC) part; and
supplying power by using a converter part by controlling a voltage output from the PFC part by using a transformer,
wherein the controlling the PFC part comprises:
setting a first switch of the converter part to at least one of a first state and a second state, based on an operating mode of the electronic apparatus, the operating mode of the electronic apparatus corresponding to at least one of a multimedia function and a lighting function; and
controlling a PFC control circuit of the PFC part based on a state of the first switch.

12. The control method of claim 11, wherein the controlling the PFC part further comprises:
based on the electronic apparatus performing the multimedia function, cutting off a supply of power to the PFC control circuit based on the first switch being on the first state; and
preventing the DC power to be transmitted by a PFC circuit to the converter part through a bypass circuit when the supply of power to the PFC control circuit is cut off.

13. The control method of claim 11, wherein the controlling the PFC part further comprises:
based on the electronic apparatus performing the lighting function, supplying power to the PFC control circuit based on the first switch being on the second state; and
controlling the PFC control circuit to transmit the DC power to the converter part through a PFC circuit.

14. The control method of claim 11, wherein the controlling the PFC part further comprises:
based on the electronic apparatus performing the lighting function, setting a second switch of the PFC part to the first state based on a signal based on the second state of the first switch and a signal output from a comparator of the PFC part, when the DC power is greater than or equal to a preset value; and
supplying power to the PFC control circuit, based on the first state of the second switch; and
operating a PFC circuit by using the power supplied to the PFC control circuit to transmit the DC power to the converter part through the PFC circuit.
